(19) United States
(12) Patent Application Publication
(10) Pub. No.: US 2026/0038315 A1
(43) Pub. Date: Feb. 5, 2026

(54) SYSTEMS AND METHODS FOR PROVIDING STEERING SYSTEM THERMAL PROGNOSTICS

(71) Applicant: Steering Solutions IP Holding Corporation, Saginaw, MI (US)

(72) Inventors: Christopher J. SOMMER, Swartz Creek, MI (US); Thomas J. STUTTS, Linwood, MI (US)

(21) Appl. No.: 19/285,723

(22) Filed: Jul. 30, 2025

Related U.S. Application Data
(60) Provisional application No. 63/677,026, filed on Jul. 30, 2024.

(51) Int. Cl. G07C 5/08; B62D 5/04; H03H 7/06

(52) U.S. Cl. CPC G07C 5/0816; B62D 5/0496; H03H 7/06

(57) ABSTRACT

A method for providing electrical component thermal prognostics includes proactively estimating a time remaining for thermal usage limits for an electrical component of a vehicle, and predicting a time estimate for thermal derating based on a fundamental first order filter response.

### CROSS REFERENCE TO RELATED APPLICATIONS

This U.S. Non-Provisional Patent application claims the benefit of and priority to U.S. Provisional Patent Application Ser. No. 63/677,026 filed Jul. 30, 2024, the contents of which are incorporated herein by reference in its entirety.

### TECHNICAL FIELD

This disclosure related to steering systems, and, in particular, to systems and methods for providing steering system thermal prognostics.

### BACKGROUND

Vehicles, such as cars, trucks, sport utility vehicles, crossovers, mini-vans, marine craft, aircraft, all-terrain vehicles, recreational vehicles, or other suitable vehicles, include a steering system, such as an electronic power steering (EPS) system, a steer-by-wire (SbW) steering system, a hydraulic steering system, or other suitable steering system. The steering system typically includes one or more controllers that control various aspects of the steering system including, but not limited to, controlling one or more electric motors and/or one or more actuators of the steering system.

### SUMMARY

This disclosure relates generally to steering systems.

An aspect of the disclosed embodiments includes a method for providing electrical component thermal prognostics. The method includes proactively estimating a time remaining for thermal usage limits for an electrical component of a vehicle, and predicting a time estimate for thermal derating based on a fundamental first order filter response.

Another aspect of the disclosed embodiments includes a system for providing steering system thermal prognostics. The system includes a processor, and a memory. The memory includes instructions that, when executed by the processor, cause the processor to: proactively estimate a time remaining for thermal usage limits for a steering system of a vehicle; and predict a time estimate for thermal derating based on a fundamental first order filter response.

Another aspect of the disclosed embodiments includes a method for providing steering system thermal prognostics. The method includes receiving a first output of a first filter associated with a steering system, receiving a first input of the first filter, and receiving a second output of the first filter. The method also includes determining, for the first filter, a time to a thermal limit based on the first output, the first input, and the second output.

Another aspect of the disclosed embodiments includes a system for providing steering system thermal prognostics. The system includes a processor, and a memory. The memory includes instructions that, when executed by the processor, cause the processor to: receive a first output of a first filter associated with a steering system; receive a first input of the first filter; receive a second output of the first filter; and determine, for the first filter, a time to a thermal limit based on the first output, the first input, and the second output.

These and other aspects of the present disclosure are disclosed in the following detailed description of the embodiments, the appended claims, and the accompanying figures.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 generally illustrates a vehicle according to the principles of the present disclosure.

FIG. 2 generally illustrates a controller according to the principles of the present disclosure.

FIG. 3 generally illustrates a flow diagram of a steering system thermal prognostic feature according to the principles of the present disclosure.

FIG. 4 generally illustrates a block diagram of the steering system thermal prognostic feature of FIG. 3.

FIG. 5 generally illustrate a first order filter according to the principles of the present disclosure.

FIG. 6 is a flow diagram generally illustrating a steering system thermal prognostics method according to the principles of the present disclosure.

FIG. 7 is a flow diagram generally illustrated an alternative steering system thermal prognostics method according to the principles of the present disclosure.

### DETAILED DESCRIPTION

The following discussion is directed to various embodiments of the disclosure. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

As described, vehicles, such as cars, trucks, sport utility vehicles, crossovers, mini-vans, marine craft, aircraft, all-terrain vehicles, recreational vehicles, or other suitable vehicles, include a steering system, such as an EPS system, a SbW steering system, a hydraulic steering system, or other suitable steering system. The steering system typically includes one or more controllers that control various aspects of the steering system including, but not limited to, controlling one or more electric motors and/or one or more actuators of the steering system.

Typically, vehicles that include SbW steering systems and/or advanced driver assistant systems (ADAS), overtime, will trend toward a thermal limit. Such a thermal limit may result in fluid degradation, seal damage, increase pump pressure, and/or the like, which may result in a degraded system response (e.g., reduced assist torque, reduced capability for meeting torque demands, and/or the like). SbW steering systems and/or ADAS systems are unable to detect (e.g., or warn of) a thermal limit before the steering system starts to thermally limit (e.g., experience degraded performance due to thermal limiting). Current technology is limited to notifying a system component after thermal limiting occurs. Further, such current technology is incapable of determining a time before steering system thermal derating.

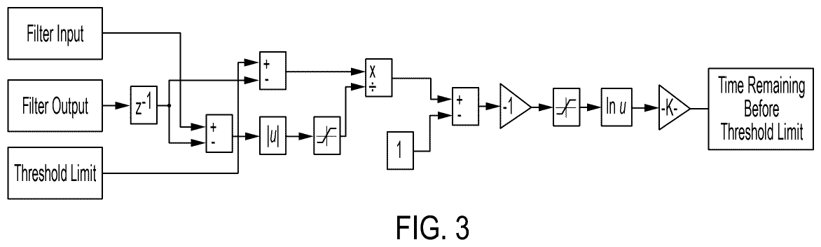

Accordingly, systems and methods, such as those described herein, configured to provide steering system thermal prognostics, may be desirable. In some embodiments, and as is generally illustrated in FIG. 3, the systems and methods described herein may be configured to proactively estimate a time remaining for thermal usage limits before the steering system reduces output capability torque. The systems and methods described herein may be configured to predict a time estimate for thermal derating based on fundamental first order filter response.

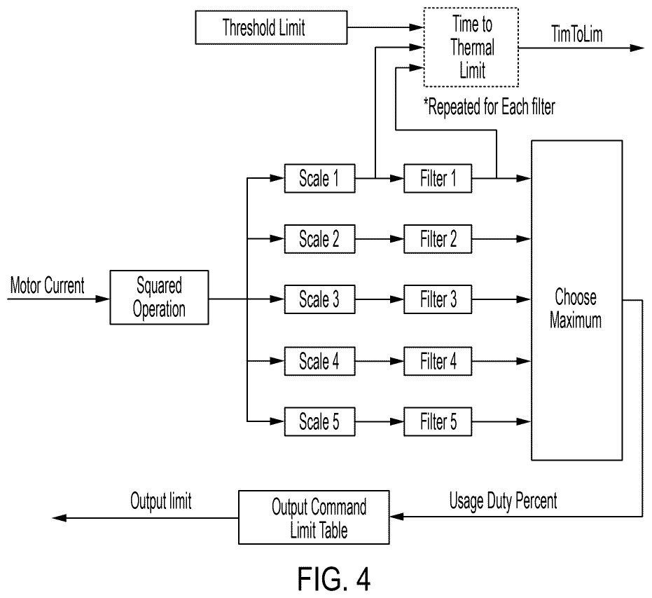

As is generally illustrated in FIG. 4, the systems and methods described herein may be configured to use a current Duty cycle strategy, such as those described in U.S. Pat. No. 6,166,502, titled “Thermal Current Limiting Apparatus and Method for Vehicle System with Electric Motor Actuator,” filed Jun. 11, 1999, the contents of which are incorporated herein in their entirety.

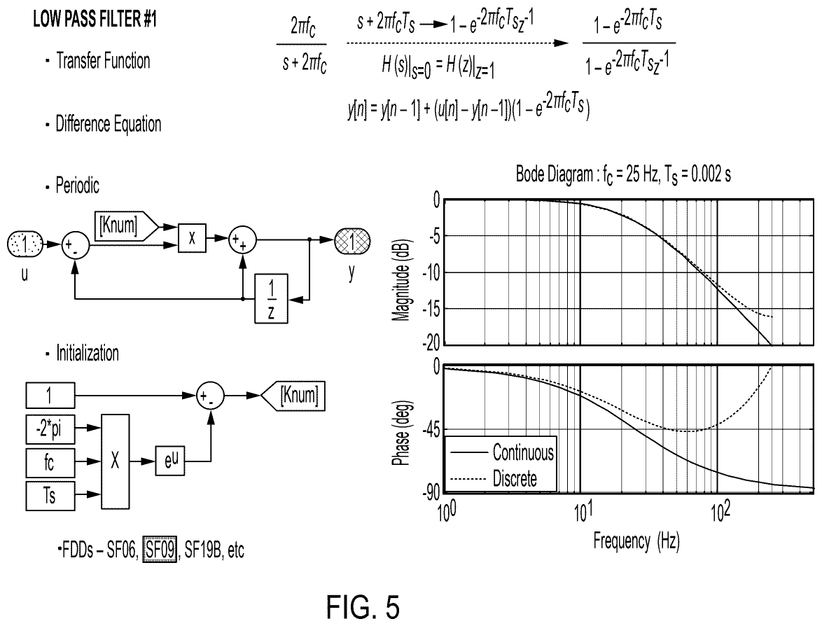

The systems and methods described herein may be configured to compare current output to a previous output to predict when the output crosses a calibratable threshold. The systems and methods described herein may be configured to provide a time to limit calculation based a predictable first order filter response, as is generally illustrated in FIG. 5. The systems and methods described herein may be configured to provide the prediction based on a present input and a previous output of the filter.

The systems and methods described herein may be configured to provide a time to thermal limit per individual filter and outputs the minimum time. The systems and methods described herein may be configured to utilize dynamic input conditions. The systems and methods described herein may be configured to back calculate a time response of given first order filter, according to:

$$y [ n ] = y [ n - 1 ] + ( u [ n ] - y [ n - 1 ] ) ( 1 - {e}^{- 2 π {f}_{c} {T}_{s}} )$$

$$Ts = - \frac{1}{2 π {f}_{c}} * ln [ - ( \frac{y [ n ] - y [ n - 1 ]}{u [ n ] - y [ n - 1 ]} - 1 ) ]$$

Where y[n]=output goal for timing, u[n]=input signal, y[n−1]=preview output signal, 1/(2πf_c)=time constant of filter, and Ts=time remaining for thermal usage limits.

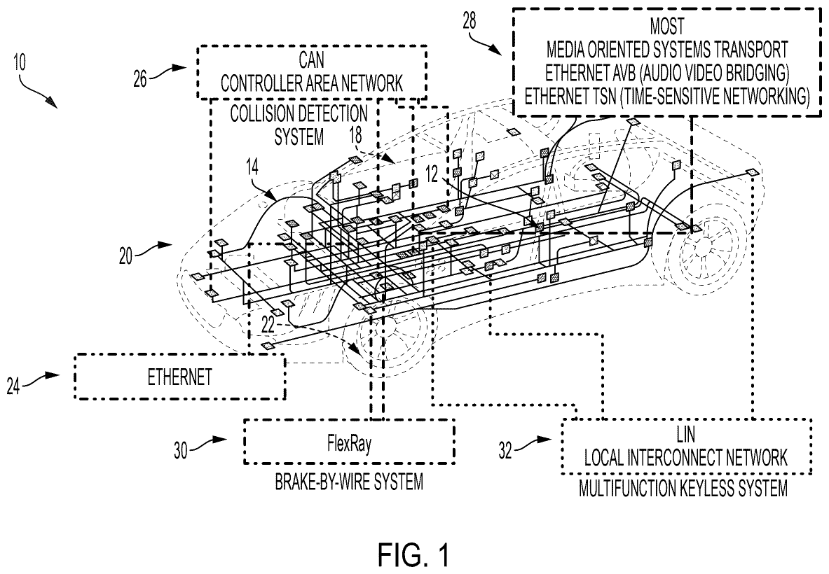

FIG. 1 generally illustrates a vehicle 10 according to the principles of the present disclosure. The vehicle 10 may include any suitable vehicle, such as a car, a truck, a sport utility vehicle, a mini-van, a crossover, any other passenger vehicle, any suitable commercial vehicle, or any other suitable vehicle. While the vehicle 10 is illustrated as a passenger vehicle having wheels and for use on roads, the principles of the present disclosure may apply to other vehicles, such as planes, boats, trains, drones, or other suitable vehicles.

The vehicle 10 includes a vehicle body 12 and a hood 14. A passenger compartment 18 is at least partially defined by the vehicle body 12. Another portion of the vehicle body 12 defines an engine compartment 20. The hood 14 may be moveably attached to a portion of the vehicle body 12, such that the hood 14 provides access to the engine compartment 20 when the hood 14 is in a first or open position and the hood 14 covers the engine compartment 20 when the hood 14 is in a second or closed position. In some embodiments, the engine compartment 20 may be disposed on rearward portion of the vehicle 10 than is generally illustrated.

The passenger compartment 18 may be disposed rearward of the engine compartment 20, but may be disposed forward of the engine compartment 20 in embodiments where the engine compartment 20 is disposed on the rearward portion of the vehicle 10. The vehicle 10 may include any suitable propulsion system including an internal combustion engine, one or more electric motors (e.g., an electric vehicle), one or more fuel cells, a hybrid (e.g., a hybrid vehicle) propulsion system comprising a combination of an internal combustion engine, one or more electric motors, and/or any other suitable propulsion system.

In some embodiments, the vehicle 10 may include a petrol or gasoline fuel engine, such as a spark ignition engine. In some embodiments, the vehicle 10 may include a diesel fuel engine, such as a compression ignition engine. The engine compartment 20 houses and/or encloses at least some components of the propulsion system of the vehicle 10. Additionally, or alternatively, propulsion controls, such as an accelerator actuator (e.g., an accelerator pedal), a brake actuator (e.g., a brake pedal), a steering wheel, and other such components are disposed in the passenger compartment 18 of the vehicle 10. The propulsion controls may be actuated or controlled by a driver of the vehicle 10 and may be directly connected to corresponding components of the propulsion system, such as a throttle, a brake, a vehicle axle, a vehicle transmission, and the like, respectively. In some embodiments, the propulsion controls may communicate signals to a vehicle computer (e.g., drive by wire) which in turn may control the corresponding propulsion component of the propulsion system. As such, in some embodiments, the vehicle 10 may be an autonomous vehicle.

In some embodiments, the vehicle 10 includes a transmission in communication with a crankshaft via a flywheel or clutch or fluid coupling. In some embodiments, the transmission includes a manual transmission. In some embodiments, the transmission includes an automatic transmission. The vehicle 10 may include one or more pistons, in the case of an internal combustion engine or a hybrid vehicle, which cooperatively operate with the crankshaft to generate force, which is translated through the transmission to one or more axles, which turns wheels 22. When the vehicle 10 includes one or more electric motors, a vehicle battery, and/or fuel cell provides energy to the electric motors to turn the wheels 22.

The vehicle 10 may include automatic vehicle propulsion systems, such as a cruise control, an adaptive cruise control, automatic braking control, other automatic vehicle propulsion systems, or a combination thereof. The vehicle 10 may be an autonomous or semi-autonomous vehicle, or other suitable type of vehicle. The vehicle 10 may include additional or fewer features than those generally illustrated and/or disclosed herein.

In some embodiments, the vehicle 10 may include an Ethernet component 24, a controller area network (CAN) bus 26, a media oriented systems transport component (MOST) 28, a FlexRay component 30 (e.g., brake-by-wire system, and the like), and a local interconnect network component (LIN) 32. The vehicle 10 may use the CAN bus 26, the MOST 28, the FlexRay Component 30, the LIN 32, other suitable networks or communication systems, or a combination thereof to communicate various information from, for example, sensors within or external to the vehicle, to, for example, various processors or controllers within or external to the vehicle. The vehicle 10 may include additional or fewer features than those generally illustrated and/or disclosed herein.

In some embodiments, the vehicle 10 may include a steering system, such as an EPS system, a steering-by-wire steering system (e.g., which may include or communicate with one or more controllers that control components of the steering system without the use of mechanical connection between the handwheel and wheels 22 of the vehicle 10), a hydraulic steering system (e.g., which may include a magnetic actuator incorporated into a valve assembly of the hydraulic steering system), or other suitable steering system.

The steering system may include an open-loop feedback control system or mechanism, a closed-loop feedback control system or mechanism, or combination thereof. The steering system may be configured to receive various inputs, including, but not limited to, a handwheel position, an input torque, one or more roadwheel positions, other suitable inputs or information, or a combination thereof.

Additionally, or alternatively, the inputs may include a handwheel torque, a handwheel angle, a motor velocity, a vehicle speed, an estimated motor torque command, other suitable input, or a combination thereof. The steering system may be configured to provide steering function and/or control to the vehicle 10. For example, the steering system may generate an assist torque based on the various inputs. The steering system may be configured to selectively control a motor of the steering system using the assist torque to provide steering assist to the operator of the vehicle 10.

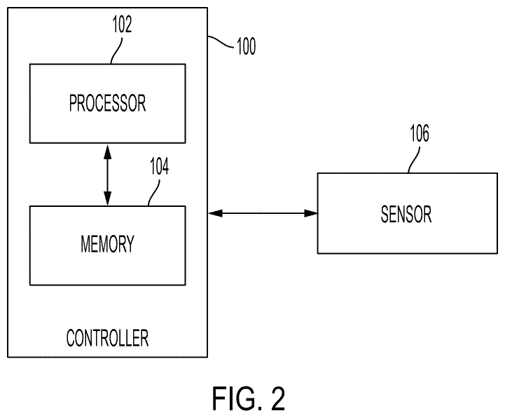

In some embodiments, the steering system may include a steering system controller, such as controller 100, as is generally illustrated in FIG. 2. The controller 100 may include any suitable controller. The controller 100 may be configured to control, for example, the various functions of the steering system. The controller 100 may include a processor 102 and a memory 104. The processor 102 may include any suitable processor, such as those described herein. Additionally, or alternatively, the controller 100 may include any suitable number of processors, in addition to or other than the processor 102. The memory 104 may comprise a single disk or a plurality of disks (e.g., hard drives), and includes a storage management module that manages one or more partitions within the memory 104. In some embodiments, memory 104 may include flash memory, semiconductor (solid state) memory or the like. The memory 104 may include Random Access Memory (RAM), a Read-Only Memory (ROM), or a combination thereof. The memory 104 may include instructions that, when executed by the processor 102, cause the processor 102 to, at least, control various functions of the steering system.

The controller 100 may receive one or more signals from various measurement devices or sensors 106 indicating sensed or measured characteristics of the vehicle 10. The sensors 106 may include any suitable sensors, measurement devices, and/or other suitable mechanisms. For example, the sensors 106 may include one or more torque sensors or devices, one or more handwheel position sensors or devices, one or more motor position sensor or devices, one or more position sensors or devices, other suitable sensors or devices, or a combination thereof. The one or more signals may indicate a handwheel torque, a handwheel angle, a motor velocity, a vehicle speed, other suitable information, or a combination thereof.

In some embodiment, the controller 100 may be configured to provide steering system thermal prognostics for the vehicle 10. For example, the controller 100 may proactively estimate a time remaining for thermal usage limits for the steering system of a vehicle 10. The controller 100 may predict a time estimate for thermal derating based on a fundamental first order filter response (e.g., using any suitable first order filter, including, but not limited to, the first order filter generally illustrated in FIG. 5).

In some embodiments, the controller 100 may receive a first output of a first filter associated with the steering system of the vehicle 10. The controller 100 may receive a first input of the first filter. The first input may be associated with a motor current of a motor associated with the steering system, and/or any other aspect of the steering system. The first output may include an output of the first filter generated prior to the first input. The controller 100 may receive a second output of the first filter. The second output may include an output of the first filter generated based on the first input. The controller may determine, for the first filter, a time to a thermal limit based on the first output, the first input, and the second output. Thee time to the thermal limit may correspond to a minimum time to the thermal limit.

In some embodiments, the controller 100 may determine the time to the thermal limit further based on a thermal limit threshold. In some embodiments, the first filter may be one of a plurality of filters. The controller 100 may determine, for each other filter of the plurality of filters, respective times to the thermal limit. The controller 100 may determine, for the steering system, a time to the thermal limit based on the time to the thermal limit for the first filter and the respective times to the thermal limit for each other filter of the plurality of filters.

In some embodiments, the controller 100 may generate a warning signal indicating the time to the thermal limit. The warning signal may include any suitable signal configured to communicate with any suitable corresponding warning mechanism including, but not limited to, one or more components of a dash or display of the vehicle 10, a mobile computing device, and/or the like. In some embodiments, the instructions further cause the processor to provide the warning signal to the corresponding warning mechanism and/or any other suitable output, display, or communication mechanism.

In some embodiments, the controller 100 may perform the methods described herein. However, the methods described herein as performed by the controller 100 are not meant to be limiting, and any type of software executed on a controller or processor can perform the methods described herein without departing from the scope of this disclosure. For example, a controller, such as a processor executing software within a computing device, can perform the methods described herein.

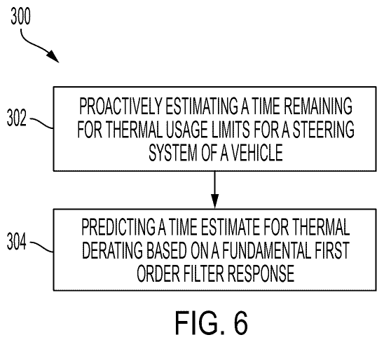

FIG. 6 is a flow diagram generally illustrating a thermal prognostics method 300 according to the principles of the present disclosure. At 302, the method 300 proactively estimates a time remaining for thermal usage limits for an electrical component (e.g., which may include, but is not limited to, a steering system) of a vehicle. For example, the controller 100 may proactively estimate the time remaining for thermal user limits for the steering system of the vehicle 10.

At 304, the method 300 predicts a time estimate for thermal derating based on a fundamental first order filter response. For example, the controller 100 may predict the time estimate for the thermal derating based on the fundamental first order filter response.

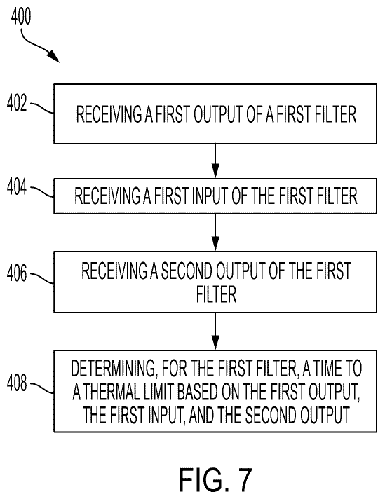

FIG. 7 is a flow diagram generally illustrated an alternative steering system thermal prognostics method 400 according to the principles of the present disclosure. At 402, the method 400 receives a first output of a first filter associated with a steering system. For example, the controller 100 may receive the first output of the first filter associated with the steering system of the vehicle 10.

At 404, the method 400 receives a first input of the first filter. For example, the controller 100 may receive the first input of the first filter.

At 406, the method 400 receives a second output of the first filter. For example, the controller 100 may receive the second output of the first filter.

At 408, the method 400 determines, for the first filter, a time to a thermal limit based on the first output, the first input, and the second output. For example, the controller 100 may determine, for the first filter, the time to the thermal limit based on the first output, the first input, and the second output.

In some embodiments, a method for providing steering system thermal prognostics includes proactively estimating a time remaining for thermal usage limits for a steering system of a vehicle, and predicting a time estimate for thermal derating based on a fundamental first order filter response.

In some embodiments, a system for providing steering system thermal prognostics includes a processor, and a memory. The memory includes instructions that, when executed by the processor, cause the processor to: proactively estimate a time remaining for thermal usage limits for a steering system of a vehicle; and predict a time estimate for thermal derating based on a fundamental first order filter response.

In some embodiments, a method for providing steering system thermal prognostics includes receiving a first output of a first filter associated with a steering system, receiving a first input of the first filter, and receiving a second output of the first filter. The method also includes determining, for the first filter, a time to a thermal limit based on the first output, the first input, and the second output.

In some embodiments, the first output is an output of the first filter generated prior to the first input. In some embodiments, the second output is an output of the first filter generated based on the first input. In some embodiments, determining the time to the thermal limit is further based on a thermal limit threshold. In some embodiments, the first input is associated with a motor current of a motor associated with the steering system. In some embodiments, the time to the thermal limit corresponds to a minimum time to the thermal limit. In some embodiments, the first filter is one of a plurality of filters. In some embodiments, the method also includes determining, for each other filter of the plurality of filters, respective times to the thermal limit. In some embodiments, the method also includes determining, for the steering system, a time to the thermal limit based on the time to the thermal limit for the first filter and the respective times to the thermal limit for each other filter of the plurality of filters. In some embodiments, the method also includes generating a warning signal indicating the time to the thermal limit. In some embodiments, the method also includes providing the warning signal.

In some embodiments, a system for providing steering system thermal prognostics includes a processor, and a memory. The memory includes instructions that, when executed by the processor, cause the processor to: receive a first output of a first filter associated with a steering system; receive a first input of the first filter; receive a second output of the first filter; and determine, for the first filter, a time to a thermal limit based on the first output, the first input, and the second output.

In some embodiments, the first output is an output of the first filter generated prior to the first input. In some embodiments, the second output is an output of the first filter generated based on the first input. In some embodiments, the instructions further cause the processor to determine the time to the thermal limit further based on a thermal limit threshold. In some embodiments, the first input is associated with a motor current of a motor associated with the steering system. In some embodiments, the time to the thermal limit corresponds to a minimum time to the thermal limit. In some embodiments, the first filter is one of a plurality of filters. In some embodiments, the instructions further cause the processor to determine, for each other filter of the plurality of filters, respective times to the thermal limit. In some embodiments, the instructions further cause the processor to determine, for the steering system, a time to the thermal limit based on the time to the thermal limit for the first filter and the respective times to the thermal limit for each other filter of the plurality of filters. In some embodiments, the instructions further cause the processor to generate a warning signal indicating the time to the thermal limit. In some embodiments, the instructions further cause the processor to provide the warning signal.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

The word “example” is used herein to mean serving as an example, instance, or illustration. Any aspect or design described herein as “example” is not necessarily to be construed as preferred or advantageous over other aspects or designs. Rather, use of the word “example” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an implementation” or “one implementation” throughout is not intended to mean the same embodiment or implementation unless described as such.

Implementations the systems, algorithms, methods, instructions, etc., described herein can be realized in hardware, software, or any combination thereof. The hardware can include, for example, computers, intellectual property (IP) cores, application-specific integrated circuits (ASICs), programmable logic arrays, optical processors, programmable logic controllers, microcode, microcontrollers, servers, microprocessors, digital signal processors, or any other suitable circuit. In the claims, the term “processor” should be understood as encompassing any of the foregoing hardware, either singly or in combination. The terms “signal” and “data” are used interchangeably.

As used herein, the term module can include a packaged functional hardware unit designed for use with other components, a set of instructions executable by a controller (e.g., a processor executing software or firmware), processing circuitry configured to perform a particular function, and a self-contained hardware or software component that interfaces with a larger system. For example, a module can include an application specific integrated circuit (ASIC), a Field Programmable Gate Array (FPGA), a circuit, digital logic circuit, an analog circuit, a combination of discrete circuits, gates, and other types of hardware or combination thereof. In other embodiments, a module can include memory that stores instructions executable by a controller to implement a feature of the module.

Further, in one aspect, for example, systems described herein can be implemented using a general-purpose computer or general-purpose processor with a computer program that, when executed, carries out any of the respective methods, algorithms, and/or instructions described herein. In addition, or alternatively, for example, a special purpose computer/processor can be utilized which can contain other hardware for carrying out any of the methods, algorithms, or instructions described herein.

Further, all or a portion of implementations of the present disclosure can take the form of a computer program product accessible from, for example, a computer-usable or computer-readable medium. A computer-usable or computer-readable medium can be any device that can, for example, tangibly contain, store, communicate, or transport the program for use by or in connection with any processor. The medium can be, for example, an electronic, magnetic, optical, electromagnetic, or a semiconductor device. Other suitable mediums are also available.

The above-described embodiments, implementations, and aspects have been described in order to allow easy understanding of the present disclosure and do not limit the present disclosure. On the contrary, the disclosure is intended to cover various modifications and equivalent arrangements included within the scope of the appended claims, which scope is to be accorded the broadest interpretation to encompass all such modifications and equivalent structure as is permitted under the law.

What is claimed is:

1. A method for providing electrical component thermal prognostics, the method comprising:
receiving a first output of a first filter associated with an electrical component;
receiving a first input of the first filter;
receiving a second output of the first filter; and
determining, for the first filter, a time to a thermal limit based on the first output, the first input, and the second output.

2. The method of claim 1, wherein the first output is an output of the first filter generated prior to the first input.

3. The method of claim 1, wherein the second output is an output of the first filter generated based on the first input.

4. The method of claim 1, wherein determining the time to the thermal limit is further based on a thermal limit threshold.

5. The method of claim 1, wherein the first input is associated with a motor current of a motor associated with the electrical component.

6. The method of claim 1, wherein the time to the thermal limit corresponds to a minimum time to the thermal limit.

7. The method of claim 1, wherein the first filter is one of a plurality of filters.

8. The method of claim 7, further comprising determining, for each other filter of the plurality of filters, respective times to the thermal limit.

9. The method of claim 8, further comprising determining, for the electrical component, a time to the thermal limit based on the time to the thermal limit for the first filter and the respective times to the thermal limit for each other filter of the plurality of filters.

10. The method of claim 1, further comprising generating a warning signal indicating the time to the thermal limit.

11. The method of claim 10, further comprising providing the warning signal.

12. A system for providing electrical component thermal prognostics, the system comprising:
a processor; and
a memory including instructions that, when executed by the processor, cause the processor to:
receive a first output of a first filter associated with an electrical component;
receive a first input of the first filter;
receive a second output of the first filter; and
determine, for the first filter, a time to a thermal limit based on the first output, the first input, and the second output.

13. The system of claim 12, wherein the first output is an output of the first filter generated prior to the first input.

14. The system of claim 12, wherein the second output is an output of the first filter generated based on the first input.

15. The system of claim 12, wherein the instructions further cause the processor to determine the time to the thermal limit further based on a thermal limit threshold.

16. The system of claim 12, wherein the first input is associated with a motor current of a motor associated with the electrical component.

17. The system of claim 12, wherein the time to the thermal limit corresponds to a minimum time to the thermal limit.

18. The system of claim 12, wherein the first filter is one of a plurality of filters.

19. The system of claim 18, wherein the instructions further cause the processor to determine, for each other filter of the plurality of filters, respective times to the thermal limit.

20. The system of claim 19, wherein the instructions further cause the processor to determine, for the electrical component, a time to the thermal limit based on the time to the thermal limit for the first filter and the respective times to the thermal limit for each other filter of the plurality of filters.

21. The system of claim 12, wherein the instructions further cause the processor to generate a warning signal indicating the time to the thermal limit.

22. The system of claim 21, wherein the instructions further cause the processor to provide the warning signal.
